(19) United States
(12) Patent Application Publication
(10) Pub. No.: US 2024/0170578 A1
(43) Pub. Date: May 23, 2024

(54) SEMICONDUCTOR DEVICE

(71) Applicant: SAMSUNG ELECTRONICS CO., LTD., Suwon-si (KR)

(72) Inventors: Seungbeck LEE, Seoul (KR); Mintae RYU, Suwon-si (KR); Minjin KWON, Hwaseong-si (KR); Hyeonjeong SUN, Seoul (KR); Wonsok LEE, Suwon-si (KR); Minhee CHO, Suwon-si (KR)

(73) Assignee: Korea Industry-University Cooperation Foundation Hanyang University, Seoul (KR)

(21) Appl. No.: 18/378,170

(22) Filed: Oct. 10, 2023

(30) Foreign Application Priority Data
Nov. 17, 2022 (KR) 10-2022-0154269

(51) Int. Cl. H01L 29/786; H01L 27/06; H01L 29/66

(52) U.S. Cl. CPC H01L 29/7869; H01L 27/0688; H01L 29/66969; H01L 29/78606; H01L 29/78648; H01L 29/78696

(57) ABSTRACT

A semiconductor device includes: a first insulation layer disposed on a substrate; a lower gate pattern disposed on the first insulation layer; a second insulation layer covering at least a portion of the lower gate pattern; a first lower gate insulation layer disposed on the lower gate pattern and the second insulation layer; a source pattern and a drain pattern disposed on the first lower gate insulation layer, wherein the source pattern and the drain pattern are spaced apart from each other to include a trench facing the lower gate pattern; an oxide semiconductor layer formed along surfaces of the source and drain patterns and a bottom surface of the trench; an upper gate insulation layer disposed on the oxide semiconductor layer; and an upper gate pattern disposed on the upper gate insulation layer and filling the trench.

### CROSS-REFERENCE TO RELATED APPLICATION

This application claims priority under 35 USC § 119 to Korean Patent Application No. No. 10-2022-0154269, filed on Nov. 17, 2022, in the Korean Intellectual Property Office (KIPO), the disclosure of which is incorporated by reference herein in its entirety.

### TECHNICAL FIELD

Example embodiments of the present inventive concept relate to a semiconductor device. More particularly, example embodiments of the present inventive concept relate to a semiconductor device including an oxide semiconductor thin film transistor (TFT) having high performance.

### DISCUSSION OF THE RELATED ART

An oxide thin film transistor, in which a transistor is formed on an oxide semiconductor layer (e.g., oxide semiconductor thin film), may be provided. Generally, the oxide thin film transistor might not be formed on an upper surface of a substrate including, e.g., silicon, and thus, the oxide thin film transistor may be formed to be spaced apart from the upper surface of the substrate. When the oxide thin film transistor is formed on the oxide semiconductor layer, it is desirable for damage to the oxide semiconductor layer to be minimized. It is desirable for the oxide semiconductor thin film transistor to have excellent channel control ability by a gate electrode. In addition, a decreasing of a short channel effect in the oxide semiconductor thin film transistor is desirable.

### SUMMARY

According to an example embodiment of the present inventive concept, a semiconductor device includes: a first insulation layer disposed on a substrate; a lower gate pattern disposed on the first insulation layer; a second insulation layer covering at least a portion of the lower gate pattern; a first lower gate insulation layer disposed on the lower gate pattern and the second insulation layer; a source pattern and a drain pattern disposed on the first lower gate insulation layer, wherein the source pattern and the drain pattern are spaced apart from each other to include a trench facing the lower gate pattern; an oxide semiconductor layer formed along surfaces of the source and drain patterns and a bottom surface of the trench; an upper gate insulation layer disposed on the oxide semiconductor layer; and an upper gate pattern disposed on the upper gate insulation layer and filling the trench.

According to an example embodiment of the present inventive concept, a semiconductor device includes: a first insulation layer disposed on a substrate; a lower gate pattern disposed on the first insulation layer; a second insulation layer covering sidewalls of the lower gate pattern; a first lower gate insulation layer disposed on the lower gate pattern and the second insulation layer; an etch stop layer covering the first lower gate insulation layer; pattern structures disposed on the etch stop layer, wherein each of the pattern structures includes a third insulation layer pattern and a conductive layer pattern stacked on each other, and the pattern structures are spaced apart from each other to include a trench overlapping the lower gate pattern; an oxide semiconductor layer formed along surfaces of the pattern structures and an upper surface of the etch stop layer in the trench; an upper gate insulation layer disposed on the oxide semiconductor layer; and an upper gate pattern disposed on the upper gate insulation layer and filling the trench.

According to an example embodiment of the present inventive concept, a semiconductor device includes: a first insulation layer disposed on a substrate; a source pattern and a drain pattern disposed on the first insulation layer, wherein the source pattern and the drain pattern are spaced apart from each other to include a trench facing a channel region; an oxide semiconductor layer formed along surfaces of the source and drain patterns and the first insulation layer in the trench; a gate insulation layer disposed on the oxide semiconductor layer; and an upper gate pattern disposed on the gate insulation layer and filling the trench.

### BRIEF DESCRIPTION OF THE DRAWINGS

The above and other features of the present inventive concept will become more apparent by describing in detail example embodiments thereof, with reference to the accompanying drawings, in which:

FIG. 1 is a cross-sectional view illustrating a semiconductor device according to an example embodiment of the present inventive concept.

FIGS. 2, 3, 4, 5, 6, 7, 8, 9, 10, 11 and 12 are cross-sectional views illustrating a method of manufacturing the semiconductor device according to an example embodiment of the present inventive concept.

FIG. 13 is a cross-sectional view illustrating a semiconductor device according to an example embodiment of the present inventive concept.

FIG. 14 is a cross-sectional view illustrating a semiconductor device according to an example embodiment of the present inventive concept.

FIG. 15 is a cross-sectional view of a semiconductor device of sample 1.

FIG. 16 is a cross-sectional view of a semiconductor device according to comparative sample 1.

FIG. 17 shows simulation results of mobility of sample 1 and comparative sample 1 according to voltage of an upper gate pattern.

### DETAILED DESCRIPTION OF THE EMBODIMENTS

Hereinafter, example embodiments of the present inventive concept will be explained in detail with reference to the accompanying drawings.

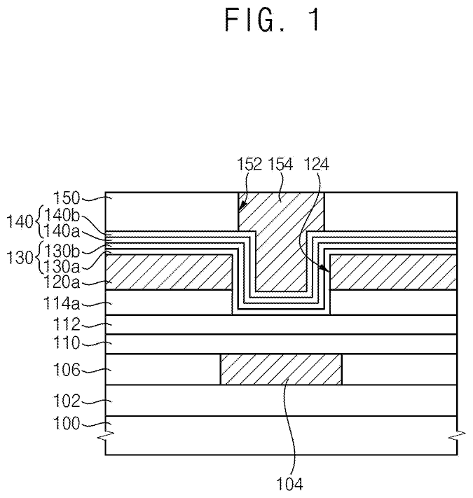

FIG. 1 is a cross-sectional view illustrating a semiconductor device according to an example embodiment of the present inventive concept.

Referring to FIG. 1, a substrate 100 may include a single crystal silicon wafer including single crystal silicon. In some example embodiments of the present inventive concept, the substrate 100 may be a wafer including a group III-V compound such as germanium, silicon-germanium, or GaP, GaAs, or GaSb. In some example embodiments of the present inventive concept, the substrate 100 may be a Silicon On Insulator (SOI) wafer or a Germanium On Insulator (GOI) wafer.

A lower structure may be formed on the substrate 100. The lower structure may include patterns constituting lower elements. In some example embodiments of the present inventive concept, the lower structure may be a front-end of line (FEOL) device. The lower structure may include, e.g., transistors, wirings, diodes, resistors, etc.

A first insulation layer 102 may be formed on the lower structure to cover the lower structure. The first insulation layer 102 may include, e.g., silicon oxide (SiO2) or silicon nitride (Si3N4). An upper surface of the first insulation layer 102 may be substantially flat.

A lower gate pattern 104 may be formed on the first insulation layer 102. The lower gate pattern 104 may include a conductive material that can be etched by an etching process. In some example embodiments of the present inventive concept, the lower gate pattern 104 may include, e.g., molybdenum, tungsten, titanium, tantalum nitride, indium tin oxide (ITO), etc.

A second insulation layer 106 may be formed on the first insulation layer 102 and may cover sidewalls of the lower gate pattern 104. The second insulation layer 106 may include, e.g., silicon oxide (SiO2) or silicon nitride (Si3N4). In some example embodiments of the present inventive concept, an upper surface of the second insulation layer 106 and an upper surface of the lower gate pattern 104 may be substantially coplanar with each other, and the upper surfaces of the second insulation layer 106 and the lower gate pattern 104 may be substantially flat.

A first lower gate insulation layer 110 may be formed on the second insulation layer 106 and the lower gate pattern 104. In some example embodiments of the present inventive concept, the first lower gate insulation layer 110 may completely cover at least an upper surface of the lower gate pattern 104.

The first lower gate insulation layer 110 may include, for example, a metal oxide having a dielectric constant higher than dielectric constants of the first and second insulation layers 102 and 106. For example, the first lower gate insulation layer 110 may have the dielectric constant higher than a dielectric constant of silicon nitride. In some example embodiments of the present inventive concept, the first lower gate insulation layer 110 may include, e.g., aluminum oxide or zirconium oxide.

An etch stop layer 112 may be formed on the first lower gate insulation layer 110 and may cover an upper surface of the first lower gate insulation layer 110. For example, the etch stop layer 112 may cover an entirety of the upper surface of the first lower gate insulation layer 110.

In some example embodiments of the present inventive concept, the etch stop layer 112 may include a material having a high etching resistance with respect to a plasma dry etching process using a fluorine-etching gas and chlorine-based etching gas. The etch stop layer 112 may include a metal oxide having a dielectric constant higher than the dielectric constants of the first and second insulation layers 102 and 106. For example, the etch stop layer 112 may have the dielectric constant higher than a dielectric constant of silicon nitride. The etch stop layer 112 may include a material different from a material of the first lower gate insulation layer 110. In some example embodiments of the present inventive concept, the etch stop layer 112 may include, e.g., hafnium oxide.

Structures in which a third insulation layer pattern 114a and a second conductive layer pattern 120a are stacked may be formed on the etch stop layer 112. A trench 124 may be formed between the structures, and the etch stop layer 112 may be exposed by a bottom surface of the trench 124.

In some example embodiments of the present inventive concept, the third insulation layer pattern 114a may include a material having a low etching resistance with respect to a plasma dry etching process using a fluorine-based etching gas and chlorine-based etching gas. The third insulation layer pattern 114a may include a material having a dielectric constant lower than the dielectric constant of the etch stop layer 112. The third insulation layer pattern 114a may include, e.g., silicon oxide (SiO2) or silicon nitride (Si3N4).

The second conductive layer pattern 120a may include a metal material that can be etched by an etching process. In some example embodiments of the present inventive concept, the second conductive layer pattern 120a may include, e.g., molybdenum, tungsten, titanium, tantalum nitride, etc. In some example embodiments of the present inventive concept, the third insulation layer pattern 114a may include the material that can be etched together in an etching process for forming the second conductive layer pattern 120a.

The trench 124, which is between the structures, may be disposed to face the upper surface of the lower gate pattern 104. For example, an entire bottom surface of the trench 124 may overlap the upper surface of the lower gate pattern 104. The second conductive layer pattern 120a may serve as a source pattern and a drain pattern of an oxide semiconductor thin film transistor. Therefore, hereinafter, the source pattern and the drain pattern are given the same reference numerals as the second conductive layer pattern 120a.

An oxide semiconductor layer 130 may be conformally formed on surfaces of the structure and the etch stop layer 112. Thus, the oxide semiconductor layer 130 may be formed on an upper surface and sidewalls of the second conductive layer pattern 120a. In some example embodiments of the present inventive concept, the oxide semiconductor layer 130 may include, e.g., indium gallium zinc oxide (IGZO), indium gallium oxide (IGO), In2O3, ZnO, Ga2O3, IGTO (indium gallium tin oxide), IZO (indium zinc oxide), ITZO (indium tin zinc oxide), etc. The oxide semiconductor layer 130 may serve as a channel layer of the oxide semiconductor thin film transistor.

In some example embodiments of the present inventive concept, the oxide semiconductor layer 130 may be formed as one layer or stacked in two or more layers. When the oxide semiconductor layer 130 is stacked in two or more layers, the oxide semiconductor layer 130 may include oxide semiconductor layers having different charge carrier concentrations.

In some example embodiments of the present inventive concept, the oxide semiconductor layer 130 may include a first oxide semiconductor layer 130a and a second oxide semiconductor layer 130b having a charge carrier concentration higher than that of the first oxide semiconductor layer 130a. In some example embodiments of the present inventive concept, the first and second oxide semiconductor layers 130a and 130b may have different charge carrier densities from each other. The first oxide semiconductor layer 130a may have a low charge carrier density due to a small oxygen vacancies and small amount of hydrogen, and thus the first oxide semiconductor layer 130a may serve as a buffer layer. The second oxide semiconductor layer 130b has a high charge carrier density due to large oxygen vacancies and a large amount of hydrogen, and thus, the second oxide semiconductor layer 130b may serve as an activation layer. The oxide semiconductor layers having different charge carrier densities from each other may be stacked on each other, so that a band gap of the channel layer may be adjusted.

In some example embodiments of the present inventive concept, the first oxide semiconductor layer 130a may include, e.g., Ga2O3, ZnO, or IGZO having a low amount of In (indium). The second oxide semiconductor layer 130b may include, e.g., ITZO, IZO, or IGZO having a high amount of In. For example, the first oxide semiconductor layer 130a may include IGZO having a low amount of In, and the second oxide semiconductor layer 130b may include IGZO having an amount of In larger than the amount of In of the IGZO included in the first oxide semiconductor layer 130a.

An upper gate insulation layer 140 may be conformally formed on the oxide semiconductor layer 130. The upper gate insulation layer 140 may be formed along a surface profile of the oxide semiconductor layer 130. The upper gate insulation layer 140 may include a metal oxide layer 140a having a high dielectric constant. The upper gate insulation layer 140 may further include a protective insulation layer 140b disposed on the metal oxide layer 140a. The protective insulation layer 140b may prevent diffusion of hydrogen ions.

For example, the metal oxide layer 140a may have a dielectric constant higher than a dielectric constant of silicon nitride. In some example embodiments of the present inventive concept, the metal oxide layer 140a may include, e.g., aluminum oxide, zirconium oxide, hafnium oxide, etc. The protective insulation layer 140b may include, e.g., silicon nitride.

A fourth insulation layer pattern 150 may be formed on the upper gate insulation layer 140. The fourth insulation layer pattern 150 may include an opening 152 exposing the upper gate insulation layer 140 of a portion of the trench 124. In some example embodiments of the present inventive concept, the fourth insulation layer pattern 150 may be formed on the upper gate insulation layer 140 facing the upper surface of the second conductive layer pattern 120a.

The fourth insulation layer pattern 150 may include a material having a dielectric constant lower than the dielectric constant of the upper gate insulation layer 140. The fourth insulation layer pattern 150 may include, e.g., silicon oxide (SiO2) or silicon nitride (Si3N4).

An upper gate pattern 154 may be formed in the opening 152, and may contact the upper gate insulation layer 140. The upper gate pattern 154 may include a metal. In some example embodiments of the present inventive concept, the upper gate pattern 154 may include, e.g., molybdenum, tungsten, titanium, tantalum nitride, etc.

An upper surface of the upper gate pattern 154 and an upper surface of the fourth insulation layer pattern 150 may be substantially coplanar with each other, and the upper surfaces of the upper gate pattern 154 and the fourth insulation layer pattern 150 may be substantially flat. The upper gate pattern 154 may protrude beyond an upper portion of the trench 124.

The semiconductor device may include the oxide semiconductor thin film transistor in which the oxide semiconductor layer 130, the source and drain patterns 120a, the first lower gate insulation layer 110, the etch stop layer 112, the lower gate pattern 104, the upper gate insulation layer 140 and the upper gate pattern 154 are included. The oxide semiconductor thin film transistor may be controlled by the lower gate pattern 104 and the upper gate pattern 154.

A third insulation layer pattern 114a may be formed between the source and drain patterns 120a and the etch stop layer 112. For example, the third insulation layer pattern 114a may be formed between the lower surfaces of the source and drain patterns 120a and the upper surface the etch stop layer 112. A stacked structure of the etch stop layer 112 and the first lower gate insulation layer 110 may serve as a lower gate insulation layer.

The oxide semiconductor layer 130 may be conformally formed along the sidewall and upper surface of the source and drain patterns 120a, and the upper gate pattern 154 may fill an opening between the source and drain patterns 120a. Therefore, when a voltage is applied to the upper gate pattern 154, charges may also be accumulated in the oxide semiconductor layer 130 facing the lower surface of the upper gate pattern 154 and the oxide semiconductor layer 130 formed on sidewalls of the source and drain patterns 120a. Therefore, channel control ability by the upper gate pattern 154 may be increased. In addition, when electric fields applied form the upper gate pattern 154 increase, an effective channel length of the upper oxide semiconductor thin film transistor may increase.

Since the oxide semiconductor layer 130 is formed on the surface of the source and drain patterns 120a, the oxide semiconductor layer 130 might not be damaged during a plasma etching process for forming the source and drain patterns 120a. Therefore, the oxide semiconductor thin film transistor may have excellent electrical characteristics.

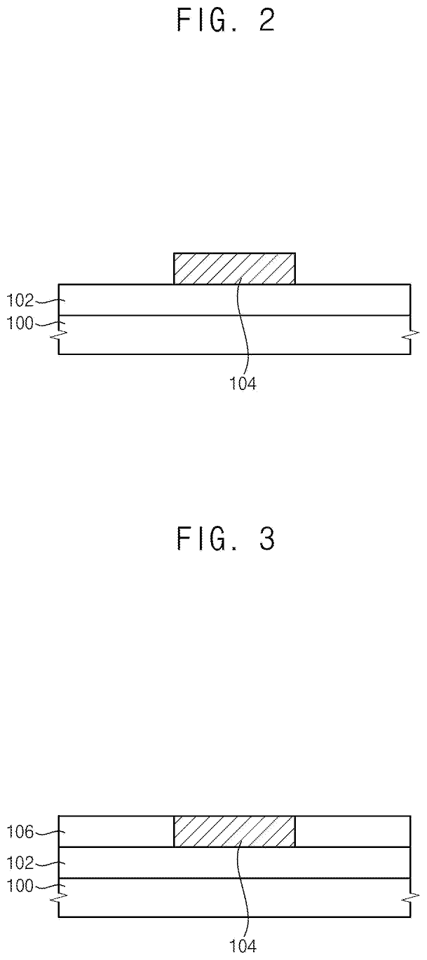

FIGS. 2 to 12 are cross-sectional views illustrating a method of manufacturing the semiconductor device according to an example embodiment of the present inventive concept.

The semiconductor device may be the semiconductor device shown in FIG. 1.

Referring to FIG. 2, a first insulation layer 102 may be formed on a substrate 100. The first insulation layer 102 may include, e.g., silicon oxide (SiO2) or silicon nitride (Si3N4). An upper surface of the first insulation layer 102 may be substantially flat.

A first conductive layer including metal may be formed on the first insulation layer 102. The metal in the first conductive layer can be etched by an etching process. In some example embodiments of the present inventive concept, the first conductive layer may include, e.g., molybdenum, tungsten, titanium, tantalum nitride, indium tin oxide (ITO), etc. The process for forming the first conductive layer may include a chemical vapor deposition (CVD) process or a physical vapor deposition (PVD) process.

The first conductive layer may be patterned by a photolithography process to form a lower gate pattern 104.

Referring to FIG. 3, a second insulation layer 106 may be formed on the lower gate pattern 104 and the first insulation layer 102. The second insulation layer 106 may cover the lower gate pattern 104. For example, the second insulation layer 106 may cover side surfaces of the lower gate pattern 104. In another example, the second insulation layer 106 may cover sides surfaces and an upper surfaces of the lower gate pattern 104. For example, an upper surface of the second insulation layer 106 may be higher than an upper surface of the lower gate pattern 104. The second insulation layer 106 may include, e.g., silicon oxide (SiO2) or silicon nitride (Si3N4). The process for forming the second insulation layer 106 may include a CVD process or a PVD process.

Thereafter, an upper portion of the second insulation layer 106 may be planarized until an upper surface of the lower gate pattern 104 may be exposed. The planarization process may include a chemical mechanical polishing (CMP) process and/or an etch-back process. Thus, the second insulation layer 106 may cover sidewalls of the lower gate pattern 104. The upper surface of the lower gate pattern 104 and an upper surface of the second insulation layer 106 may be substantially coplanar with each other, and the upper surfaces of the lower gate pattern 104 and the second insulation layer 106 may be substantially flat.

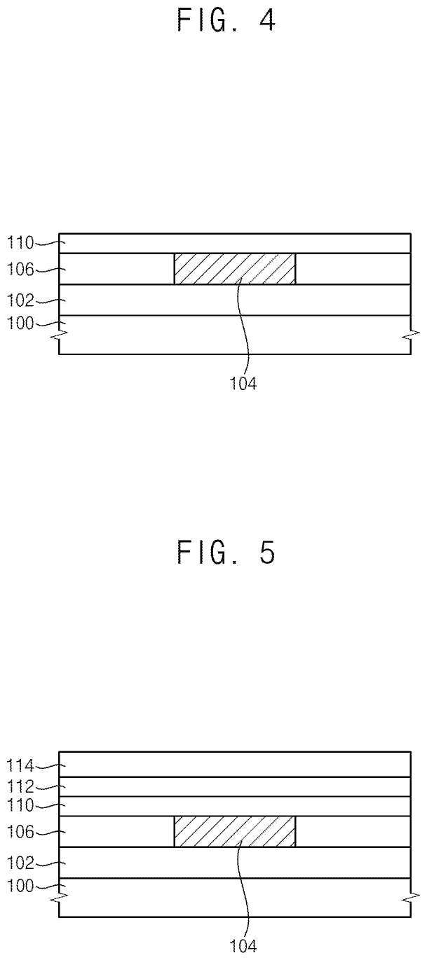

Referring to FIG. 4, a first lower gate insulation layer 110 may be formed on the lower gate pattern 104 and the second insulation layer 106. The first lower gate insulation layer 110 may include a metal oxide having a dielectric constant higher than dielectric constants of the first and second insulation layers 102 and 106. For example, the first lower gate insulation layer 110 may have the dielectric constant higher than a dielectric constant of silicon nitride. In some example embodiments of the present inventive concept, the first lower gate insulation layer 110 may include, e.g., aluminum oxide or zirconium oxide. The process for forming the first lower gate insulation layer 110 may include a CVD process or an atomic layer deposition (ALD) process.

Referring to FIG. 5, an etch stop layer 112 may be formed on the first lower gate insulation layer 110. A third insulation layer 114 may be formed on the etch stop layer 112. The etch stop layer 112 may cover an upper surface of the first lower gate insulation layer 110. For example, the etch stop layer 112 may cover an entire upper surface of the first lower gate insulation layer 110.

The etch stop layer 112 may include a material having a high etch resistance with respect to a plasma dry etching process using a fluorine-based etching gas and chlorine-based etching gas. The etch stop layer 112 may remain without removing in subsequent processes, and the etch stop layer 112 may serve as a second lower gate insulation layer. For example, a stacked structure including the first lower gate insulation layer 110 and the etch stop layer 112 may serve as a lower gate insulation layer of a lower transistor.

The etch stop layer 112 may include a metal oxide having a dielectric constant higher than the dielectric constants of the first and second insulation layers 102 and 106. For example, the etch stop layer 112 may have the dielectric constant higher than a dielectric constant of silicon nitride. The etch stop layer 112 may include a material different from a material of the first lower gate insulation layer 110. In some example embodiments of the present inventive concept, the etch stop layer 112 may include, e.g., hafnium oxide. The process for forming the etch stop layer 112 may include a CVD process or an ALD process.

The third insulation layer 114 may include a material having a low etching resistance with respect to a plasma dry etching process using a fluorine-based etching gas and chlorine-based etching gas. The third insulation layer 114 may include a material having a dielectric constant lower than the dielectric constant of the etch stop layer 112. The third insulation layer 114 may include, e.g., silicon oxide (SiO2) or silicon nitride (Si3N4). The process for forming the third insulation layer 114 may include a CVD process or a PVD process.

Referring to FIG. 6, a second conductive layer 120 including metal may be formed on the third insulation layer 114. The metal included in the second conductive layer 120 can be etched by an etching process. In some example embodiments of the present inventive concept, the second conductive layer 120 may include, e.g., molybdenum, tungsten, titanium, tantalum nitride, etc. For example, the process for forming the second conductive layer 120 may include a CVD process or a PVD process.

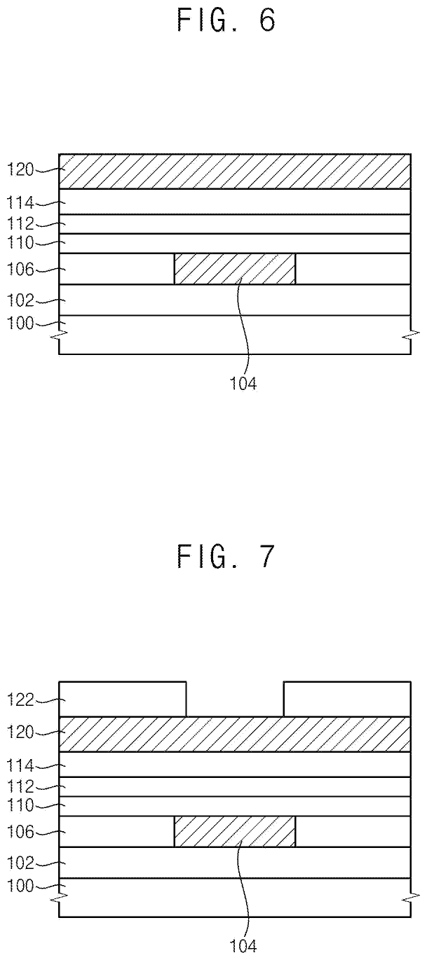

Referring to FIG. 7, a hard mask layer may be formed on the second conductive layer 120. The hard mask layer may be patterned by a photolithography process to form a hard mask pattern 122.

A region covered by the hard mask pattern 122 may be a region for forming source and drain patterns 120a of the lower transistor. A region exposed by the hard mask pattern 122 may be a region for forming a channel of a lower transistor. An entire region exposed by the hard mask pattern 122 may completely overlap the lower gate pattern 104.

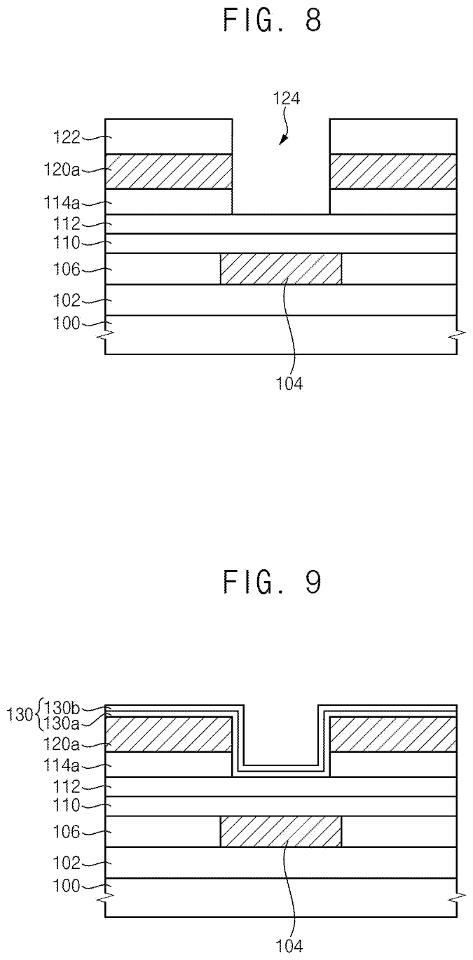

Referring to FIG. 8, the second conductive layer 120 and the third insulation layer 114 may be etched using the hard mask pattern 122 as an etch mask. The etching process may be performed to expose the etch stop layer 112. For example, the etching process may include a plasma dry etching process using a fluorine-based etching gas and chlorine-based etching gas. In some example embodiments of the present inventive concept, the etching gas may include e.g., CF4, SF6, Cl2, etc.

Accordingly, structures in which a third insulation layer pattern 114a and a second conductive layer pattern 120a are stacked may be formed on the etch stop layer 112. A trench 124 may be formed between the structures, and the etch stop layer 112 may be exposed by a bottom surface of the trench 124. The second conductive layer pattern 120a may serve as the source pattern and the drain pattern of the lower transistor.

As such, the source and drain patterns 120a and the trench 124 therebetween may be formed by a single photolithography process (e.g., one photo process and one etching process) Therefore, processes for forming the source and drain patterns 120a and the trench 124 may be simplified.

After the etching process, the hard mask pattern 122 may be removed.

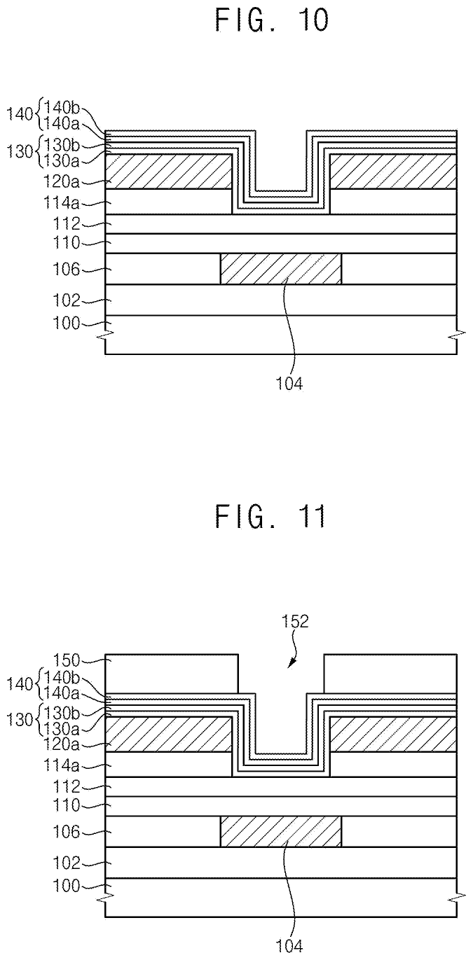

Referring to FIG. 9, an oxide semiconductor layer 130 may be formed along surfaces of the structure, in which the third insulation layer pattern 114a and the second conductive layer pattern 120a are stacked, and the etch stop layer 112. The oxide semiconductor layer 130 may be conformally formed on the surfaces of the structure and the etch stop layer 112. In some example embodiments of the present inventive concept, the oxide semiconductor layer 130 may include, e.g., IGZO, IGO, In2O3, ZnO, Ga2O3, IGTO, IZO, ITZO, etc. For example, the oxide semiconductor layer 130 may be formed by an ALD process. The oxide semiconductor layer 130 may serve as a channel layer of an oxide semiconductor thin film transistor subsequently formed.

In some example embodiments of the present inventive concept, the oxide semiconductor layer 130 may be formed as a single layer, or may be formed by stacking two or more layers. In some example embodiments of the present inventive concept, the oxide semiconductor layer 130 may include oxide semiconductor layers having different charge carrier concentrations from each other. For example, the oxide semiconductor layer 130 may include a first oxide semiconductor layer 130a and a second oxide semiconductor layer 130b having a charge carrier concentration higher than a charge carrier concentration of the first oxide semiconductor layer 130a. The first oxide semiconductor layer 130a may include, e.g., Ga2O3, ZnO, or IGZO having a low amount of In. The second oxide semiconductor layer 130b may include, e.g., ITZO, IZO, or IGZO having a high amount of In.

Before forming the oxide semiconductor layer 130, the source pattern and the drain pattern 120a of the oxide semiconductor thin film transistor may be formed. Therefore, the oxide semiconductor layer 130 might not be damaged during the process for forming the source and drain patterns 120a. Therefore, the oxide semiconductor thin film transistor subsequently formed may have excellent electrical characteristics.

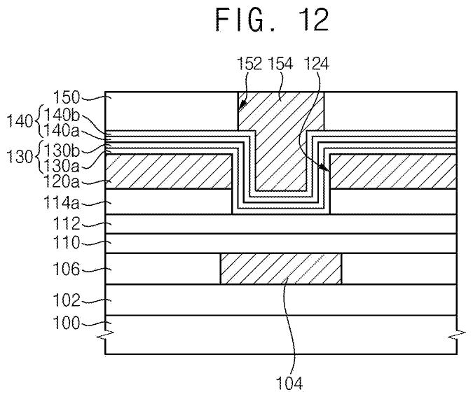

Referring to FIG. 10, an upper gate insulation layer 140 may be formed on the oxide semiconductor layer 130. The upper gate insulation layer 140 may include at least a metal oxide layer 140a having a high dielectric constant. In addition, the upper gate insulation layer 140 may further include a protective insulation layer 140b on the metal oxide layer 140a. The protective insulation layer 140b may prevent diffusion of hydrogen ions.

For example, the metal oxide layer 140a may have a dielectric constant higher than a dielectric constant of silicon nitride. In some example embodiments of the present inventive concept, the metal oxide layer 140a may include, e.g., aluminum oxide, zirconium oxide, hafnium oxide, etc. The protective insulation layer 140b may include, e.g., silicon nitride. For example, the process for forming the metal oxide layer 140a and the protective insulation layer 140b may include a CVD process or an ALD process.

Referring to FIG. 11, a fourth insulation layer may be formed on the upper gate insulation layer 140. The fourth insulation layer may include a material having a dielectric constant lower than a dielectric constant of a material included in the upper gate insulation layer 140. The fourth insulation layer may include, e.g., silicon oxide (SiO2) or silicon nitride (Si3N4). An upper surface of the fourth insulation layer may be planarized.

The fourth insulation layer may fill the trench. A height of an upper surface of the fourth insulation layer may be higher than a height of an upper gate pattern subsequently formed.

The portion of the fourth insulation layer formed in the trench and a portion of the fourth insulation layer adjacent to the trench may be etched to form a fourth insulation layer pattern 150. The fourth insulation layer pattern 150 may include an opening 152. The opening 152 may be a mold pattern for forming an upper gate pattern. The upper gate insulation layer 140 may be exposed by a bottom of the opening 152.

Referring to FIG. 12, a third conductive layer may be formed on the fourth insulation layer pattern 150 to fill the opening 152. In some example embodiments of the present inventive concept, the third conductive layer may include, e.g., molybdenum, tungsten, titanium, tantalum nitride, etc. For example, the process for forming the third conductive layer may include a CVD process or a PVD process.

The third conductive layer may be planarized until the upper surface of the fourth insulation layer pattern 150 may be exposed and an upper gate pattern 154 may be formed.

By the above process, a semiconductor device including the oxide semiconductor thin film transistor may be manufactured. The oxide semiconductor thin film transistor may include the upper gate pattern 154 and the lower gate pattern 104 formed on and under the oxide semiconductor layer 130, respectively. The oxide semiconductor thin film transistor may be controlled by the upper gate pattern 154 and the lower gate pattern 104.

As described above, the source and drain patterns 120a and the trench 124 therebetween may be formed by a single photolithography process. Therefore, the patterning process of the source and drain patterns 120a and the trench 124 therebetween may be simplified. In addition, since the oxide semiconductor layer 130 is formed after forming the source and drain patterns 120a, the oxide semiconductor layer 130 might not be damaged during the etching process for forming the source and drain patterns 120a. Thus, the oxide semiconductor thin film transistor may have excellent electrical characteristics.

In addition, since the oxide semiconductor layer 130 is conformally formed along the sidewalls and upper surfaces of the source and drain patterns 120a, charges may also be accumulated in the oxide semiconductor layer 130 that is disposed on the sidewall of the source and drain patterns 120a by a voltage applied to the upper gate pattern 154. Thus, an effective channel length of the oxide semiconductor thin film transistor may be increased.

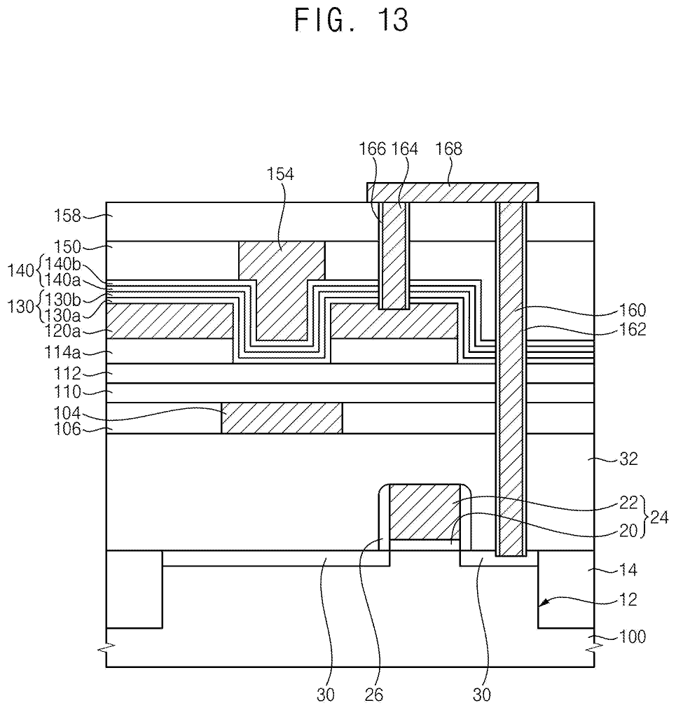

FIG. 13 is a cross-sectional view illustrating a semiconductor device according to an example embodiment of the present inventive concept.

Referring to FIG. 13, the substrate 100 may be a single crystal silicon substrate including single crystal silicon.

An isolation trench 12 may be formed at an upper portion of the substrate 100, and an isolation pattern 14 may be formed in the isolation trench 12. An upper surface of the substrate 100 may be divided into a field region, where the isolation pattern 14 is formed, and an active region that corresponds to a portion of the substrate 100 that is between the isolation patterns 14.

A first gate structure 24 may be formed on the substrate 100, and the first gate structure 24 may include a first gate insulation layer 20 and a first gate pattern 22. Spacers 26 may be formed on sidewalls of the first gate structure 24. A first source/drain region 30 doped with N-type or P-type impurities may be formed at the active region adjacent to sides of the first gate structure 24. Accordingly, a first transistor including the first gate structure 24 and the first source/drain region 30 may be formed on the substrate 100. The first transistor may include an N-type transistor and/or a P-type transistor. A channel region of the first transistor may be formed at the substrate that includes the single crystal silicon, and thus, the first transistor may be a silicon-based transistor.

A lower insulating interlayer 32 may be formed on the first transistor to cover the first transistor.

The oxide semiconductor thin film transistor shown in FIG. 1 may be formed on the lower insulating interlayer 32.

For example, the oxide semiconductor thin film transistor, in which the lower gate pattern 104, the first lower gate insulation layer 110, the etch stop layer 112, the third insulation layer pattern 114a, the second conductive layer pattern 120a, the oxide semiconductor layer 130, the upper gate insulation layer 140 and the upper gate pattern 154 are included, may be formed on the lower insulating interlayer 32. The second insulation layer 106 may be formed on a sidewall of the lower gate pattern 104, and the fourth insulation layer pattern 150 may be formed on a sidewall of the upper gate pattern 154. The second conductive layer pattern 120a may serve as the source/drain pattern of the oxide semiconductor thin film transistor.

The upper insulating interlayer 158 may be formed on the fourth insulation layer pattern 150 and the upper gate pattern 154.

Wirings may be electrically connected with the first transistor and/or the oxide semiconductor thin film transistor.

In some example embodiments of the present inventive concept, a first contact plug 160 may pass through the upper insulating interlayer 158, the fourth insulation layer pattern 150, the upper gate insulation layer 140, the oxide semiconductor layer 130, the etch stop layer 112, the first lower gate insulation layer 110, the second insulation layer 106 and the lower insulating interlayer 32. The first contact plug 160 may be connected to the first source/drain region 30 of the first transistor. A first insulation spacer 162 may be formed on a sidewall of the first contact plug 160.

In some example embodiments of the present inventive concept, a second contact plug 164 may pass through upper insulating interlayer 158, the fourth insulation layer pattern 150, the upper gate insulation layer 140 and the oxide semiconductor layer 130. The second contact plug 164 may be connected to the second conductive layer pattern 120a. A second insulation spacer 166 may be formed on a sidewall of the second contact plug 164. A line pattern 168 connected to the first contact plug 160 and/or the second contact plug 164 may be formed on the upper insulating interlayer 158. In some example embodiments of the present inventive concept, the first transistor and the oxide semiconductor thin film transistor may be electrically connected to each other, so that a designed circuit may be formed. For example, the first transistor and the oxide semiconductor thin film transistor may be electrically connected to each other through the first contact plug 160, the second contact plug 164, and the line pattern 168.

As such, in the semiconductor device, the silicon-based transistor (e.g., the first transistor) may be formed on the substrate, and the oxide semiconductor thin film transistor may be formed over the silicon-based transistor.

FIG. 14 is a cross-sectional view illustrating a semiconductor device according to some example embodiments of the present inventive concept.

The semiconductor device illustrated in FIG. 14 may include the upper gate pattern without a lower gate pattern (see, e.g., lower gate pattern 104 of FIG. 1). For example, the semiconductor device may be the same as the semiconductor device shown in FIG. 1, except that a lower gate pattern, a lower gate insulation layer, and an etch stop layer are not included in the semiconductor device.

Referring to FIG. 14, the semiconductor device may include a lower structure on the substrate 100. The first insulation layer 102 may be formed on the lower structure to cover the lower structure.

Structures, in which the third insulation layer pattern 114a and the second conductive layer pattern 120a are stacked, may be formed on the first insulation layer 102.

The oxide semiconductor layer 130 may be conformally formed along surfaces of the structure and the first insulation layer 102. Thus, the oxide semiconductor layer 130 may be formed on an upper surface and a sidewall of the second conductive layer pattern 120a.

For example, the oxide semiconductor layer 130 may include the first oxide semiconductor layer 130a and the second oxide semiconductor layer 130b having a charge carrier concentration higher than having a charge carrier concentration of the first oxide semiconductor layer 130a.

The upper gate insulation layer 140 may be conformally formed on the oxide semiconductor layer 130 along a surface of the oxide semiconductor layer 130. The upper gate insulation layer 140 may include a metal oxide layer 140a having a high dielectric constant. The upper gate insulation layer 140 may further include the protective insulation layer 140b disposed on the metal oxide layer 140a. The protective insulation layer 140b may prevent diffusion of hydrogen ions.

The fourth insulation layer pattern 150 including the opening 152 may be formed on the upper gate insulation layer 140. The upper gate pattern 154 may be formed in the opening 152, and the upper gate pattern 154 may contact the upper gate insulation layer 140.

As described above, the semiconductor device may include the upper gate pattern without a lower gate pattern.

A comparison of effective channel length according to gate electric fields will be discussed below.

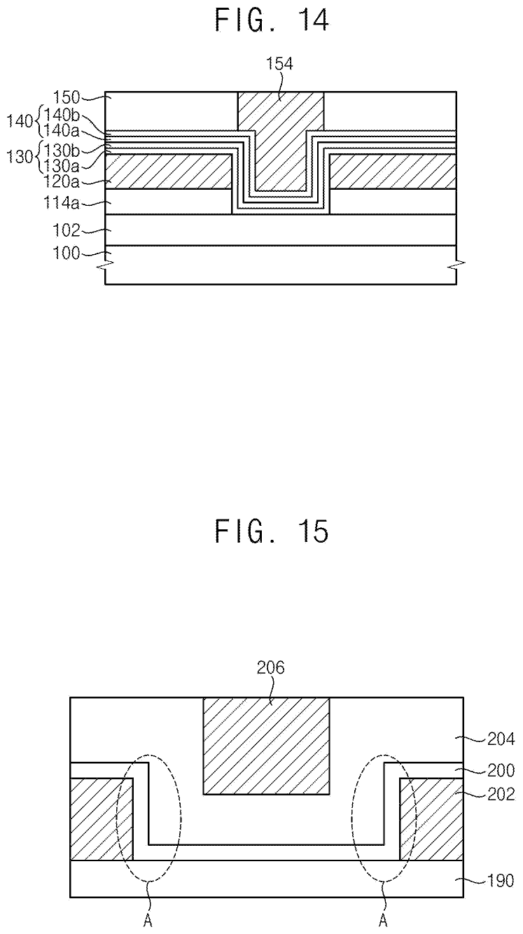

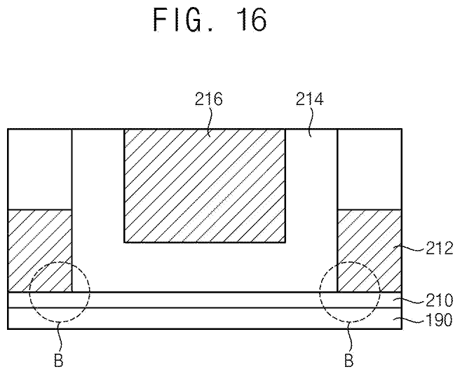

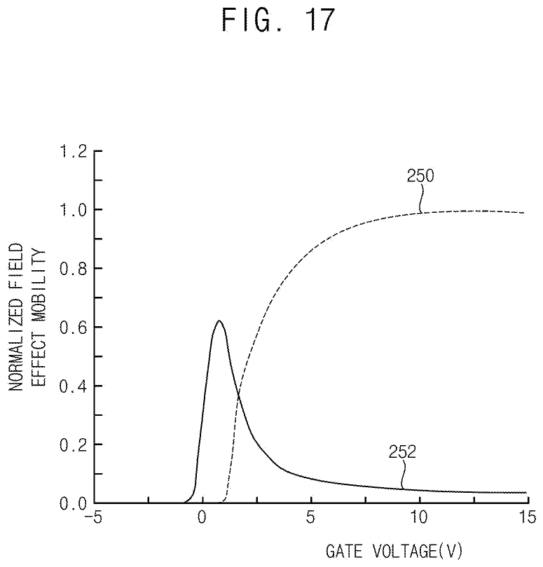

FIG. 15 is a cross-sectional view of a semiconductor device of sample 1, and FIG. 16 is a cross-sectional view of a semiconductor device according to a comparative sample 1.

Sample 1

Referring to FIG. 15, the semiconductor device of sample 1 includes source and drain patterns 202, an oxide semiconductor layer 200, an upper gate insulation layer 204, and an upper gate pattern 206 sequentially stacked on an insulation layer 190, which has a flat surface. The oxide semiconductor layer 200 may cover sidewalls and upper surfaces of the source and drain patterns 202 and a portion of the insulation layer 190 that is between the source and drain patterns 202. The oxide semiconductor layer 200 does not contact a bottom surface of the source and drain patterns 202.

For example, the oxide semiconductor layer 200 is formed of IGZO having a thickness of about 10 nm. The source/drain pattern 202 has a thickness of about 50 nm, and a distance between the source and drain patterns 202 is about 150 nm. For example, the upper gate insulation layer 204 is formed of aluminum oxide having a thickness of about 30 nm. A gate length of the upper gate pattern 206 is about 90 nm.

Comparative Sample 1

Referring to FIG. 16, the semiconductor device of comparative sample 1 includes an oxide semiconductor layer 210, a source pattern, a drain pattern 212, an upper gate insulation layer 214, and an upper gate pattern 216 formed on an insulation layer 190, which has a flat surface. The source and drain patterns 212 are disposed on an upper surface of the oxide semiconductor layer 210. The oxide semiconductor layer 210 contacts a bottom surface of the source and drain patterns 212.

For example, the oxide semiconductor layer 210 is formed of IGZO having a thickness of about 10 nm. The source/drain pattern 212 has a thickness of about 50 nm, and the distance between the source and drain patterns 212 is about 150 nm. For example, the upper gate insulation layer 214 is formed of aluminum oxide having a thickness of about 30 nm. The gate length of the upper gate pattern 206 is about 70 nm.

When a voltage is applied to the upper gate pattern 206 of sample 1, charges may be further accumulated in the oxide semiconductor layer (200, portion A) on the sidewall of the source and drain patterns 202 by electric fields generated from the upper gate pattern 206. When the electric fields applied from the upper gate pattern 206 increases, an effective channel length of the semiconductor device may increase. Therefore, channel control ability by the upper gate pattern 206 may be increased.

When a voltage is applied to the upper gate pattern 216 of comparative sample 1, electric fields generated in the upper gate pattern 216 may be blocked by the source and drain patterns 212. Accordingly, charges might not be accumulated in the oxide semiconductor layer (210, portion B) contacting the bottom surface of the source and drain patterns 212. Therefore, the effective channel length of the oxide semiconductor layer 210 might not be increased by the electric fields generated in the upper gate pattern 216.

Comparison Characteristic Data

FIG. 17 shows simulation results of mobility of sample 1 and comparative sample 1 according to voltage of the upper gate pattern.

Referring to FIG. 17, reference numeral 250 denotes a mobility of the semiconductor device of sample 1 according to a voltage applied to the upper gate pattern 206, and reference numeral 252 denotes a mobility of the semiconductor device of comparative sample 1 according to a voltage applied to the upper gate pattern 216.

In a case of the sample 1, when the voltage applied to the upper gate pattern 206 is increased, an effective channel length is increased by the electric fields applied from the upper gate pattern 206. As the electric fields applied from the upper gate pattern 206 increases, a field effect mobility of the sample 1 increases.

In a case of the comparative sample 1, electric fields applied from the upper gate pattern 216 is blocked by the source and drain patterns 212. Therefore, when the voltage applied to the upper gate pattern 216 is increased, the field effect mobility increases to have a maximum value at a specific voltage, and then decreases again to converge to zero.

While the present inventive concept has been described with reference to example embodiments thereof, it will be understood by those of ordinary skill in the art that various changes in form and details may be made thereto without departing from the spirit and scope of the present inventive concept.

What is claimed is:

1. A semiconductor device, comprising:
a first insulation layer disposed on a substrate;
a lower gate pattern disposed on the first insulation layer;
a second insulation layer covering at least a portion of the lower gate pattern;
a first lower gate insulation layer disposed on the lower gate pattern and the second insulation layer;
a source pattern and a drain pattern disposed on the first lower gate insulation layer, wherein the source pattern and the drain pattern are spaced apart from each other to include a trench facing the lower gate pattern;
an oxide semiconductor layer formed along surfaces of the source and drain patterns and a bottom surface of the trench;
an upper gate insulation layer disposed on the oxide semiconductor layer; and
an upper gate pattern disposed on the upper gate insulation layer and filling the trench.

2. The semiconductor device of claim 1, wherein each of the source pattern and the drain pattern includes a metal that can be etched by an etching process.

3. The semiconductor device of claim 2, wherein each of the source pattern and the drain pattern includes at least one of molybdenum, tungsten, titanium, or tantalum nitride.

4. The semiconductor device of claim 1, further comprising insulation layer patterns disposed on a bottom surface of each of the source pattern and the drain pattern.

5. The semiconductor device of claim 1, further comprising an etch stop layer disposed on the first lower gate insulation layer.

6. The semiconductor device of claim 5, wherein the first lower gate insulation layer and the etch stop layer include different materials from each other, and
wherein each of the first lower gate insulation layer and the etch stop layer includes metal oxides having dielectric constants higher than a dielectric constant of silicon nitride.

7. The semiconductor device of claim 5, wherein the oxide semiconductor layer is formed on sidewalls and upper surfaces of the source and drain patterns, wherein the oxide semiconductor layer is formed in the trench such that it is formed on an upper surface of the etch stop layer.

8. The semiconductor device of claim 1, wherein the oxide semiconductor layer includes IGZO, IGO, In2O3, ZnO, Ga2O3, IGTO, IZO, or ITZO.

9. The semiconductor device according to claim 1, wherein the oxide semiconductor layer has a structure in which a plurality of oxide semiconductor layers having different charge carrier concentrations from each other are stacked.

10. The semiconductor device according to claim 1, wherein the oxide semiconductor layer has a stacked structure including a first oxide semiconductor layer and a second oxide semiconductor layer having a charge carrier concentration higher than a charge carrier concentration of the first oxide semiconductor layer.

11. The semiconductor device of claim 1, further comprising a protective insulation layer disposed on the oxide semiconductor layer to prevent diffusion of hydrogen ions.

12. The semiconductor device of claim 1, wherein the substrate includes a silicon substrate, and further comprises a lower structure including a silicon based transistor disposed on the silicon substrate.

13. A semiconductor device, comprising:
a first insulation layer disposed on a substrate;
a lower gate pattern disposed on the first insulation layer;
a second insulation layer covering sidewalls of the lower gate pattern;
a first lower gate insulation layer disposed on the lower gate pattern and the second insulation layer;
an etch stop layer covering the first lower gate insulation layer;
pattern structures disposed on the etch stop layer, wherein each of the pattern structures includes a third insulation layer pattern and a conductive layer pattern stacked on each other, and the pattern structures are spaced apart from each other to include a trench overlapping the lower gate pattern;
an oxide semiconductor layer formed along surfaces of the pattern structures and an upper surface of the etch stop layer in the trench;
an upper gate insulation layer disposed on the oxide semiconductor layer; and
an upper gate pattern disposed on the upper gate insulation layer and filling the trench.

14. The semiconductor device of claim 13, wherein the conductive layer pattern includes a source pattern and a drain pattern, wherein each of the source pattern and the drain pattern includes a metal that can be etched by an etching process.

15. The semiconductor device of claim 13, wherein the third insulation layer pattern includes an insulation material having a dielectric constant lower than a dielectric constant of the etch stop layer.

16. The semiconductor device of claim 13, wherein the first lower gate insulation layer and the etch stop layer include different materials from each other, and
wherein each of the first lower gate insulation layer and the etch stop layer includes metal oxides having dielectric constants higher than a dielectric constant of silicon nitride.

17. The semiconductor device of claim 16, wherein the first lower gate insulation layer includes aluminum oxide or zirconium oxide, and the etch stop layer includes hafnium oxide.

18. The semiconductor device according to claim 13, wherein the oxide semiconductor layer has a stacked structure including a first oxide semiconductor layer and a second oxide semiconductor layer having a charge carrier concentration higher than a charge carrier concentration of the first oxide semiconductor layer.

19. A semiconductor device, comprising:
a first insulation layer disposed on a substrate;
a source pattern and a drain pattern disposed on the first insulation layer, wherein the source pattern and the drain pattern are spaced apart from each other to include a trench facing a channel region;
an oxide semiconductor layer formed along surfaces of the source and drain patterns and the first insulation layer in the trench;
a gate insulation layer disposed on the oxide semiconductor layer; and
an upper gate pattern disposed on the gate insulation layer and filling the trench.

20. The semiconductor device of claim 19, wherein the gate insulation layer includes a metal oxide layer and a protective insulation layer.
